(19) United States
(12) Patent Application Publication
(10) Pub. No.: US 2006/0251971 A1
(43) Pub. Date: Nov. 9, 2006

(54) Photo-Mask with variable transmission by ion implantation

(76) Inventor: Richard Schenker, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/121,507

(22) Filed: May 3, 2005

(51) Int. Cl. G03F 1/00; H01L 21/00

(52) U.S. Cl. 430/5; 438/942; 438/800

(57) ABSTRACT

Some embodiments of the present invention include photo-masks with variable transmission by ion implantation.

### TECHNICAL FIELD

Embodiments of the invention relate to photolithography. In particular, embodiments of the invention relate to methods and apparatus for photo-masks.

### BACKGROUND

In semiconductor processing, a pattern of features may be transferred from a photo-mask to the surface of a semiconductor wafer using photolithography. As photolithography patterns smaller features, it becomes more sensitive to photo-mask feature design and sizing errors. Photo-masks typically include limited features with discrete transmittance values. For example, a binary photo-mask may have features with two discrete transmittance values resulting in a mask with highly transparent areas and highly opaque areas. In another example, an embedded phase shift mask may have features with three discrete transmittance values: highly transparent, highly opaque, and highly transparent with a half-wavelength optical path length difference. In fabricating photo-masks having limited, discrete transmittance areas, techniques such as optical proximity correction (OPC) and improved manufacturing methods may be used to reduce sensitivity to feature design and sizing errors.

### BRIEF DESCRIPTION OF THE DRAWINGS

The invention is illustrated by way of example and not by way of limitation in the figures of the accompanying drawings, in which the like references indicate similar elements and in which:

FIGS. 1A-E illustrate cross sectional type views of a method in accordance with one embodiment of the present invention.

FIGS. 2A-E illustrate cross sectional type views of a method in accordance with one embodiment of the present invention.

FIGS. 3A-D illustrate cross sectional type views of a method in accordance with one embodiment of the present invention.

FIGS. 4A-F illustrate cross sectional type views of a method in accordance with one embodiment of the present invention.

FIG. 5 illustrates a cross sectional type views of an apparatus in accordance with one embodiment of the present invention.

FIG. 6 illustrates a cross sectional type views of an apparatus in accordance with one embodiment of the present invention.

FIG. 7 illustrates an operational flow in accordance with one embodiment of the present invention.

### DETAILED DESCRIPTION

In the following description, various embodiments relating to photo-masks will be described. However, various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Various operations will be described as multiple discrete operations in turn. However, the order of description should not be construed as to imply that these operations are necessarily order dependent. In particular, these operations need not be performed in the order of presentation.

Photo-mask quality may be enhanced by providing areas of variable transmission. In particular, superior wafer images may be achieved through photolithography using photo-masks having modulated transmission areas. As discussed below, areas of variable transmission may be used for improved optical proximity correction (OPC) or to solve the problem of bright corners that occurs on some dark features of the photo-mask pattern. Also as discussed below, areas of variable transmission may be used to solve the problem of sizing errors that are inherent in photo-mask fabrication. In general, a variable transmission area may include an area having a local transmittance, or transmission (transmission equals transmittance squared), that may be modulated to vary from the discrete transmission values available in photo-mask fabrication.

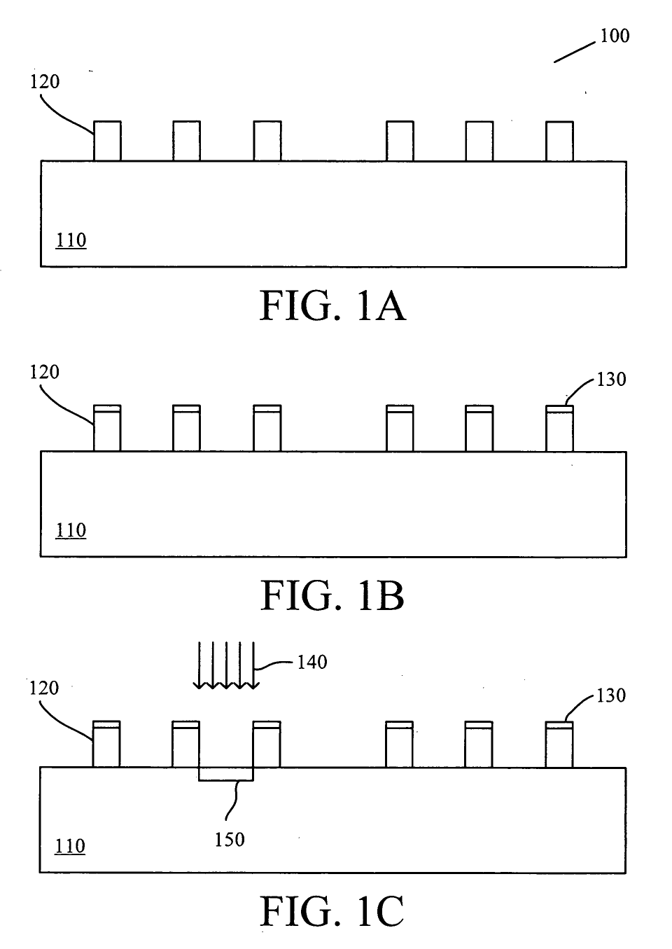

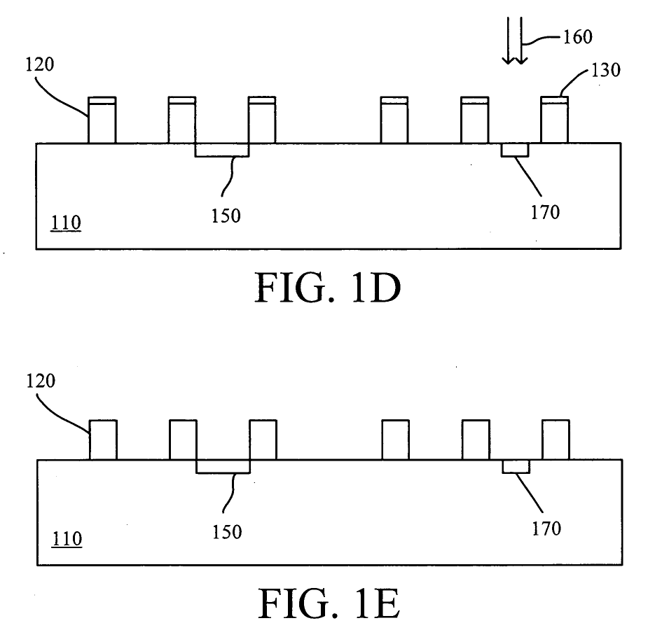

FIGS. 1A-E illustrate cross sectional views of a method for fabricating a photo-mask having areas of variable transmittance.

FIG. 1A illustrates a photo-mask 100 that includes a substrate 110 and elements 120. FIG. 1A illustrates only a portion of photo-mask 100 for the sake of clarity. Substrate 110 may be any suitable material. In an embodiment, substrate 110 may include a transparent material. In an embodiment, substrate 110 may include a homogenous material having a high transmittance. In some embodiments, substrate 110 may include glass. In an embodiment, the transmittance of substrate 110 may be in the range of about 95 to 100%. In another embodiment, the transmittance of substrate 110 may be in the range of about 98 to 100%.

Elements 120 may include any suitable material and may form a pattern on substrate 110. In an embodiment, elements 120 may be dark features. In some embodiments, it may be desired to transfer the pattern formed by elements 120 to a photo-sensitive film on a semiconductor surface via photolithography.

In some embodiments, photo-mask 100 may be a binary photo-mask. In such embodiments, elements 120 may include any suitable absorbing material. In an embodiment, elements 120 may include chrome. In another embodiment, elements 120 may have a transmittance in the range of about 0 to 15%. In an embodiment, elements 120 may have a transmittance in the range of about 0 to 5%.

In some embodiments, photo-mask 100 may be an embedded phase shift mask (EPSM). In such embodiments, elements 120 may include any suitable mostly absorbing material. In an embodiment, elements 120 may have a transmittance of less than about 50%. In an embodiment, elements 120 may have a transmittance that is in the range of about 20 to 50%. In an embodiment, elements 120 may have a transmittance in the range of about 20 to 60%. In another embodiment, elements 120 may have a transmittance in the range of about 30 to 50%. In another embodiment, elements 120 may have a 180-degree relative phase with respect to substrate 110.

In some embodiments, photo-mask 100 may be a chromeless phase shift mask. In such embodiments, elements 120 may include any suitable mostly transmitting material. In an embodiment, elements 120 may have a transmittance that is greater than about 50%. In an embodiment, elements 120 may have a transmittance in the range of about 60 to 80%. In another embodiment, elements 120 may have a transmittance in the range of about 80 to 100%. In another embodiment, elements 120 may have a 180-degree relative phase with respect to substrate 110.

As illustrated in FIG. 1B, a protective material 130 may be formed over elements 120. Protective material 130 may be any suitable material. In an embodiment, protective material 130 may include chrome. In some embodiments, however, protective material 130 may not be required. For example, if the performance of elements 120 is not impacted by atomic implantation, as further discussed below, protective material 130 may not be required.

As illustrated in FIG. 1C, a selective implant 140 may be performed to form implant region 150. Implant region 150 may create a corresponding variable transmission region in substrate 110 such that the transmittance through implant region 150 is less than the transmittance through substrate 110.

Selective implant 140 may be performed by any available technique. In an embodiment, selective implant 140 may include an ion beam implant. In an embodiment, selective implant 140 may include an implant at an acceleration voltage in the range of about 20 to 40 kV. In an embodiment, selective implant 140 may include an implant at an acceleration voltage in the range of about 30 to 45 kV. In another embodiment, selective implant 140 may include an implant at an acceleration voltage in the range of about 40 to 100 kV. In an embodiment, selective implant 140 may be performed at a dosage in the range of about 1×10¹⁶ to 1×10¹⁸ atoms/cm². In another embodiment, selective implant 140 may be performed at a dosage in the range of about 1×10¹⁷ to 1×10¹⁸ atoms/cm². In an embodiment, selective implant 140 may be performed at a dosage in the range of about 5×10¹⁶ to 5×10¹⁷ atoms/cm².

Selective implant 140 may include any suitable implant species. In an embodiment, selective implant 140 may include Silicon. In another embodiment, selective implant 140 may include Gallium.

Selective implant 140 may form an implant region 150 of any concentration. In an embodiment, implant region 150 may have a maximum implant concentration in the range of about 2×10¹⁹ to 5×10²¹ atoms/cm³. In another embodiment, implant region 150 may have a maximum implant concentration in the range of about 1×10¹⁹ to 1×10²² atoms/cm³. In an embodiment, implant region 150 may have a maximum implant concentration in the range of about 1×10²⁰ to 1×10²¹ atoms/cm³.

As discussed, implant region 150 may have a transmittance that is less than the transmittance of substrate 110. Selective implant 140 may be performed to affect a change in transmittance in substrate 110. In some embodiments, the implant concentration required to affect a reduction of about 1% of transmission may be in the range of about 1×10¹⁹ to 1×10²⁰ atoms/cm³. Implant region 130 may have any transmittance. In an embodiment, implant region 130 may have a transmittance in the range of about 60 to 95%. In an embodiment, implant region 130 may have a transmittance in the range of about 60 to 99%. In another embodiment, implant region 130 may have a transmittance in the range of about 55 to 80%.

As illustrated in FIG. 1D, a selective implant 160 may be performed to form implant region 170. Implant region 170 may create a corresponding variable transmission region in substrate 110 such that the transmittance through implant region 170 is less than the transmittance through substrate 110. In an embodiment, the transmittance through implant region 170 may be different than the transmittance through implant region 150.

Selective implant 160 may be performed by any available technique. In an embodiment, selective implant 160 may include an ion beam implant. In an embodiment, selective implant 160 may include an implant at an acceleration voltage in the range of about 20 to 40 kV. In an embodiment, selective implant 160 may include an implant at an acceleration voltage in the range of about 30 to 45 kV. In another embodiment, selective implant 160 may include an implant at an acceleration voltage in the range of about 25 to 35 kV. In an embodiment, selective implant 160 may be performed at a dosage in the range of about 1×10¹⁶ to 1×10¹⁸ atoms/cm². In another embodiment, selective implant 160 may be performed at a dosage in the range of about 1×10¹⁷ to 1×10¹⁸ atoms/cm². In an embodiment, selective implant 160 may be performed at a dosage in the range of about 5×10¹⁶ to 5×10¹⁷ atoms/cm².

Selective implant 160 may include any suitable implant species. In an embodiment, selective implant 160 may include Silicon. In another embodiment, selective implant 160 may include Gallium.

Selective implant 160 may form an implant region 170 of any concentration. In an embodiment, implant region 170 may have a maximum implant concentration in the range of about 2×10¹⁹ to 5×10²¹ atoms/cm³. In another embodiment, implant region 170 may have a maximum implant concentration in the range of about 1×10¹⁹ to 1×10²² atoms/cm³. In an embodiment, implant region 170 may have a maximum implant concentration in the range of about 1×10²⁰ to 1×10²¹ atoms/cm³.

As discussed, implant region 170 may have a transmittance that is less than the transmittance of substrate 110. Implant region 130 may have any transmittance. In an embodiment, implant region 130 may have a transmittance in the range of about 60 to 95%. In an embodiment, implant region 130 may have a transmittance in the range of about 60 to 99%. In another embodiment, implant region 130 may have a transmittance in the range of about 55 to 80%.

As illustrated in FIG. 1D, implant regions 150, 170 may be formed between elements 120. However, implant regions may be formed anywhere on substrate 110 where a variable transmission is desired. Further, any number of variable transmission areas may be formed by repeating selective implant steps. The variable transmission areas may be of similar transmittance or have any number of different transmittances. In an embodiment, there may be 3 variable transmission areas. In another embodiment, there may be in the range of 3 to 10 variable transmission areas. In an embodiment, there may be in the range of about 2 to 15 variable transmission areas.

As illustrated in FIG. 1E, protective material 130 (if any) may be removed by any suitable technique. In an embodiment, protective material 130 may be removed by laser.

In some embodiments, an anneal may be performed to integrate the implant species or to target the transmittance of the implant region. In an embodiment, an anneal may be performed after each implant step. In another embodiment, an anneal may be performed after several implant steps. In an embodiment, an anneal may be performed or after all implant steps.

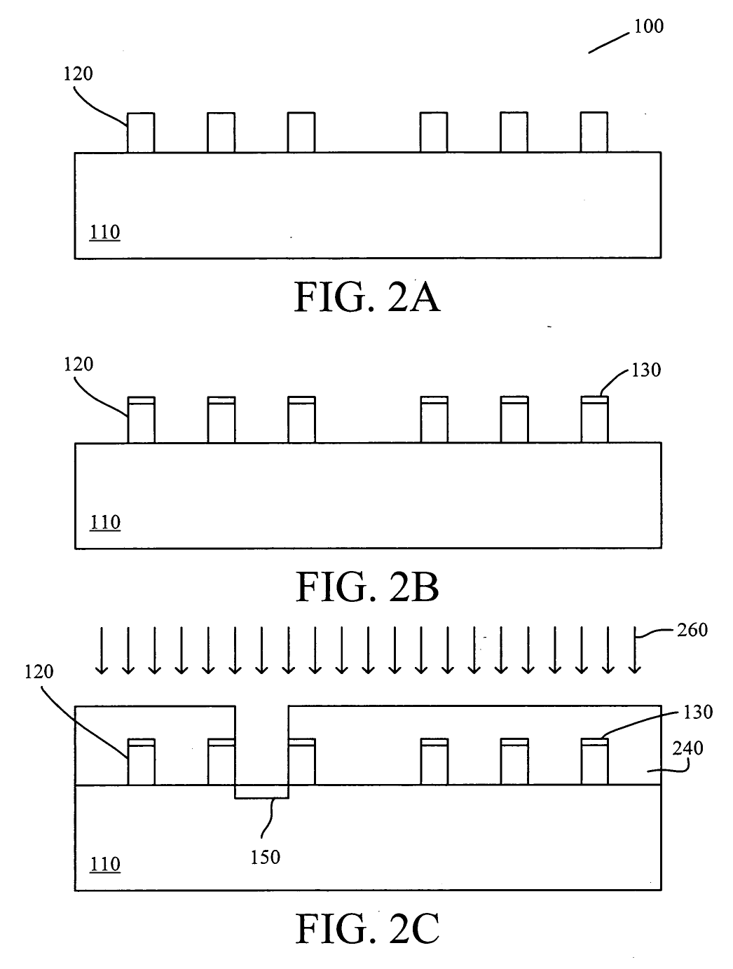

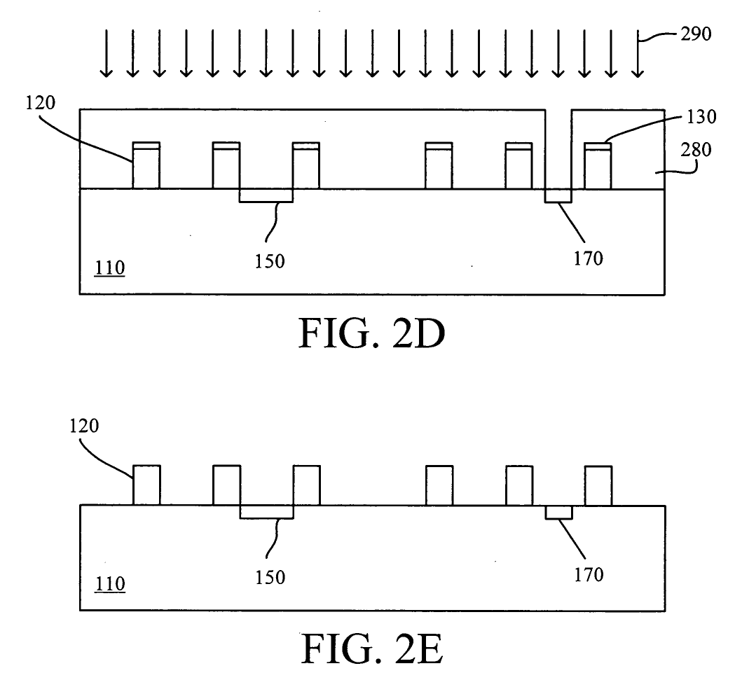

FIGS. 2A-E illustrate cross sectional views of a method for fabricating a photo-mask having areas of variable transmittance.

FIG. 2A illustrates a photo-mask 100 that includes a substrate 110 and elements 120.

As illustrated in FIG. 2B, a protective material 130 may be formed over elements 120. In some embodiments, protective material 130 may not be required.

As illustrated in FIG. 2C, a patterned layer 240 may be formed over substrate 1 10, elements 120, and protective material 130 (if any) and an implant 260 may be performed to form implant region 150. Patterned layer 240 may be formed by any suitable technique and may contain any suitable material. Patterned layer 240 may include openings to expose areas of substrate 110 to an implant while protecting other areas.

Implant 260 may be performed by any suitable technique. In an embodiment, implant 260 may include a blanket implant. In an embodiment, implant 260 may include an implant at an acceleration voltage in the range of about 20 to 40 kV. In an embodiment, implant 260 may include an implant at an acceleration voltage in the range of about 30 to 45 kV. In another embodiment, implant 260 may include an implant at an acceleration voltage in the range of about 25 to 35 kV. In an embodiment, implant 260 may be performed at a dosage in the range of about 1×10¹⁶ to 1×10¹⁸ atoms/cm². In another embodiment, implant 260 may be performed at a dosage in the range of about 1×10¹⁷ to 1×10¹⁸ atoms/cm². In an embodiment, implant 260 may be performed at a dosage in the range of about 5×10¹⁶ to 5×10¹⁷ atoms/cm².

As illustrated in FIG. 2D, patterned layer 240 may be removed, a patterned layer 280 may be formed over substrate 110, elements 120, protective material 130 (if any), and implant region 150, and an implant 290 may be performed to form implant region 170.

Patterned layer 240 may be removed by any available technique. Patterned layer 280 may be formed by any suitable technique and may contain any suitable material. Patterned layer 280 may include openings to expose areas of substrate 110 to an implant while protecting other areas.

Implant 290 may be performed by any suitable technique. In an embodiment, implant 290 may include a blanket implant. In an embodiment, implant 290 may include an implant at an acceleration voltage in the range of about 20 to 40 kV. In an embodiment, implant 290 may include an implant at an acceleration voltage in the range of about 30 to 45 kV. In another embodiment, implant 290 may include an implant at an acceleration voltage in the range of about 25 to 35 kV. In an embodiment, implant 290 may be performed at a dosage in the range of about 1×10¹⁶ to 1×10¹⁸ atoms/cm³. In another embodiment, implant 290 may be performed at a dosage in the range of about 1×10¹⁷ to 1×10¹⁸ atoms/cm³. In an embodiment, implant 290 may be performed at a dosage in the range of about 5×10¹⁶ to 5×10¹⁷ atoms/cm³.

As illustrated in FIG. 2D, implant regions may be formed between elements 120. However, implant regions may be formed anywhere on substrate 110 where a variable transmission is desired. Further, any number of variable transmission areas may be formed by repeating the patterning and implant steps. The variable transmission areas may be of similar transmittance or have any number of different transmittances. In an embodiment, there may be 3 variable transmission areas. In another embodiment, there may be in the range of 3 to 10 variable transmission areas. In an embodiment, there may be in the range of about 2 to 15 variable transmission areas.

As illustrated in FIG. 2E, protective material 130 (if any) may be removed by any suitable technique. In an embodiment, protective material 130 may be removed by laser.

In some embodiments, an anneal may be performed to integrate the implant species or to target the transmittance of the implant region. In an embodiment, an anneal may be performed after each implant step. In another embodiment, an anneal may be performed after several implant steps. In an embodiment, an anneal may be performed or after all implant steps.

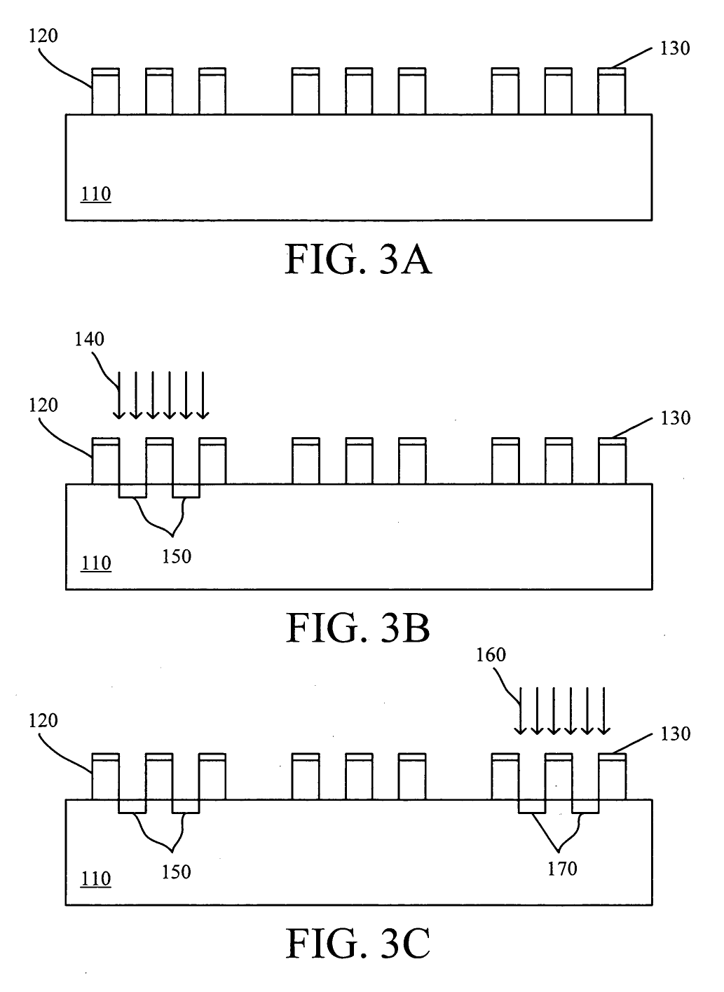

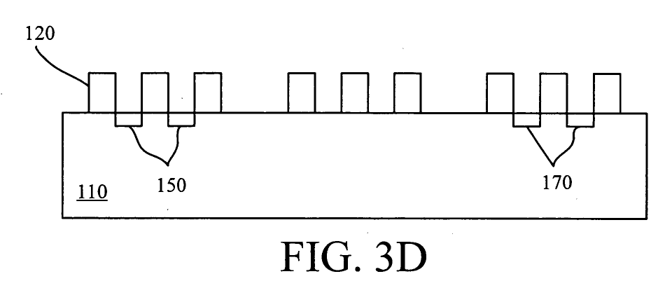

FIGS. 3A-E illustrate cross sectional views of a method for fabricating a photo-mask having areas of variable transmittance.

FIG. 3A illustrates substrate 110, elements 120 and protective material 130. In some embodiments, protective material 130 may not be required. As illustrated in FIG. 3B, a selective implant 140 may form implant region 150 in substrate 110 in analogy to FIG. 1C. FIG. 3B illustrates that selective implant 140 and implant region 150 may overlay several elements 120 to affect a change in transmittance in substrate 110.

As illustrated in FIG. 3C, a selective implant 160 may form implant region 170 in substrate 110 in analogy to FIG. 1D. FIG. 3C illustrates that selective implant 160 and implant region 170 may overlay several elements 120 to affect a change in transmittance in substrate 110.

The apparatus illustrated in FIG. 3D may also be formed by a method analogous to the method illustrated in FIGS. 2A-E. That is, implant regions 150, 170 may be formed by forming a pattern layer, performing an implant, and removing the pattern layer.

As discussed in reference to FIGS. 1A-E and 2A-E, any number of variable transmission areas may be formed by either repeating selective implant steps or repeating patterning and implant steps.

As illustrated in FIG. 3D, protective material 130 (if any) may be removed by any suitable technique. In an embodiment, protective material 130 may be removed by laser.

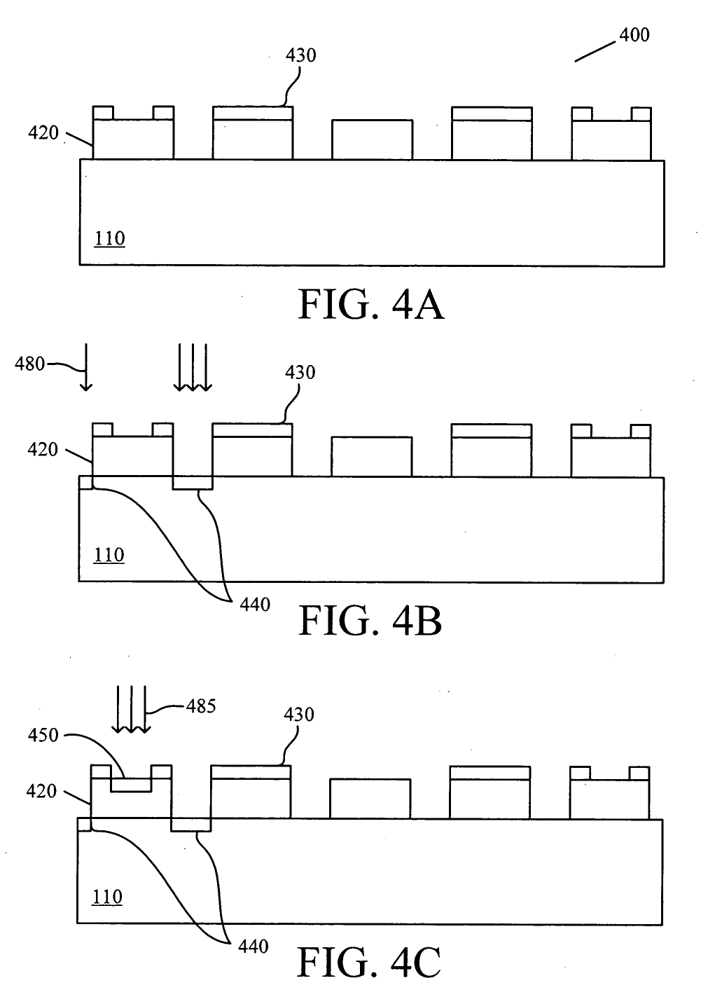

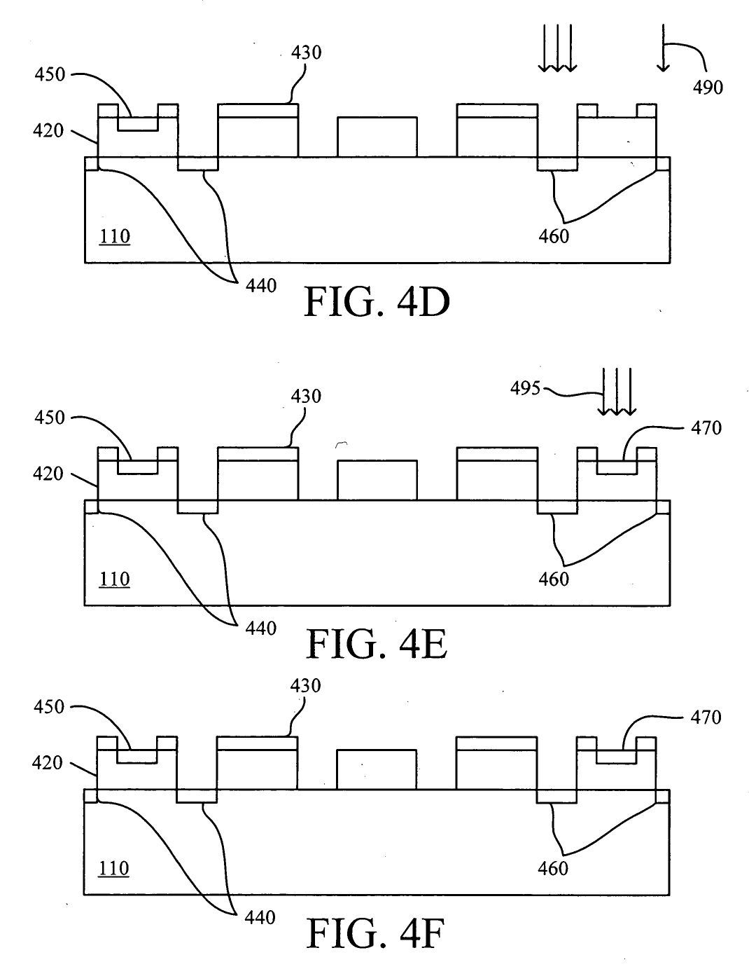

FIGS. 4A-F illustrate cross sectional views of a method for fabricating a photo-mask having areas of variable transmittance.

FIG. 4A illustrates a photo-mask 400 including substrate 110, elements 420, and absorbing elements 430. In some embodiments, photo-mask may be an alternating phase shift mask. In an embodiment, elements 420 may include the same material as substrate 110. In an embodiment, elements 420 may be formed by etching portions of substrate 110. In an embodiment, elements 420 may have a half-wavelength optical path-length difference with respect to substrate 110. In an embodiment, absorbing elements 430 may include chrome. In another embodiment, absorbing elements 430 may have a transmittance in the range of about 0 to 15%. In an embodiment, absorbing elements 430 may have a transmittance in the range of about 0 to 5%.

As illustrated in FIGS. 4B-E, selective implants 480, 485, 490, 495 may be performed to form implant regions 440, 450, 460, 470, respectively, to form the photo-mask illustrated in FIG. 4F. Implant regions 440, 450, 460, 470 may cause variable transmission regions such that the transmittance through implant regions 440, 450, 460, 470 is less than the transmittance through substrate 110.

Selective implants 480, 485, 490, 495 may be performed by any available technique. In an embodiment, selective implants 480, 485, 490, 495 may include an ion beam implant. In another embodiment, selective implants 480, 485, 490, 495 may include masking with a patterned layer, performing a blanket implant, and removing the patterned layer. In an embodiment, selective implants 480, 485, 490, 495 may include implants at an acceleration voltage in the range of about 20 to 40 kV. In an embodiment, selective implants 480, 485, 490, 495 may include implants at an acceleration voltage in the range of about 30 to 45 kV. In another embodiment, selective implants 480, 485, 490, 495 may include implants at an acceleration voltage in the range of about 25 to 35 kV. In an embodiment, selective implants 480, 485, 490, 495 may be performed at a dosage in the range of about 1×10¹⁶ to 1×10¹⁸ atoms/cm³. In another embodiment, selective implants 480, 485, 490, 495 may be performed at a dosage in the range of about 1×10¹⁷ to 1×10¹⁸ atoms/cm³. In an embodiment, selective implants 480, 485, 490, 495 may be performed at a dosage in the range of about 5×10¹⁶ to 5×10¹⁷ atoms/cm³.

Selective implants 480, 485, 490, 495 may include any suitable implant species. In an embodiment, selective implants 480, 485, 490, 495 may include Silicon. In another embodiment, selective implants 480, 485, 490, 495 may include Gallium.

Selective implants 480, 485, 490, 495 may form implant regions 440, 450, 460, 470 of any concentrations. In an embodiment, implant regions 440, 450, 460, 470 may have implant concentrations in the range of about 2×10¹⁹ to 5×10²¹ atoms/cm³. In another embodiment, implant regions 440, 450, 460, 470 may have implant concentrations in the range of about 1×10¹⁹ to 1×10²¹ atoms/cm³. In an embodiment, implant regions 440, 450, 460, 470 may have implant concentration in the range of about 1×10²⁰ to 1×10²¹ atoms/cm₃.

Implant regions 440, 450, 460, 470 may have transmittances that are less than the transmittance of substrate 110. In some embodiments, the implant concentration required to affect a reduction of about 1% of transmission value may be approximately 3×10¹⁹ atoms/cm³. Implant regions 440, 450, 460, 470 may have any transmittance values. In an embodiment, implant regions 440, 450, 460, 470 may have a transmittance values in the range of about 60 to 95%. In an embodiment, implant regions 440, 450, 460, 470 may have a transmittance values in the range of about 60 to 99%. In another embodiment, implant regions 440, 450, 460, 470 may have a transmittance values in the range of about 55 to 80%.

Further, any number of variable transmission areas may be formed by repeating the illustrated selective implant or repeating patterning, implant, and pattern removal. In an embodiment, there may be 5 variable transmission areas. In another embodiment, the number of implant region types may be in the range of 5 to 10 variable transmission areas. In an embodiment, the number of implant region types may be in the range of about 2 to 15 variable transmission areas. In some embodiments, the transmission value of each implant region type may be a different value. In an embodiment, the transmittance of regions 450, 470 may be less than the transmittance of regions 440, 460, respectively, to compensate for reduced light intensity due to interaction with the walls of elements 420.

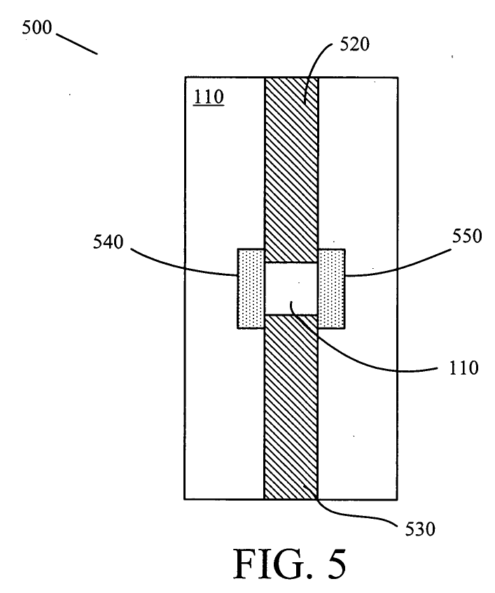

FIG. 5 illustrates a photo-mask 500 in accordance with an embodiment of the invention. Photo-mask 500 may utilize variable transmission areas and OPC to reduce the problem of bright corners on dark features which is inherent in photo-mask design. FIG. 5 illustrates substrate 110, dark features 520, 530, and variable transmission regions 540, 550. Dark features 520, 530 may be any suitable design feature. In various embodiments, dark features 520, 530 may include binary photo-mask features, EPSM features, chromeless phase shift mask features, or alternating phase shift mask features.

As illustrated in FIG. 5, dark features 520, 530 may be lines whose ends terminate near each other. However, dark features 520, 530 may be in any orientation that causes bright corners, such as, for example, a line terminating near a perpendicular line. The distance between dark features 520, 530 may be any value. In an embodiment, the distance between dark features 520, 530 may be in the range of about 60 to 100 nm. In another embodiment, the distance between dark features 520, 530 may be in the range of about 65 to 75 nm. In an embodiment, the distance between dark features 520, 530 may be in the range of about 50 to 80 nm.

Further, FIG. 5 illustrates variable transmission regions 540, 550 as rectangles extending beyond the ends of dark features 520, 530 toward the line portion of the dark feature. However, transmission regions 540, 550 may be of any suitable shape and need not extend beyond the ends of the dark features toward the line portion of the dark features. Variable transmission regions 540, 550 may extend beyond the ends of dark features 520, 530 by any suitable length. In an embodiment, variable transmission regions 540, 550 may extend beyond the ends of dark features 520, 530 by a distance in the range of about 5 to 15 nm. In another embodiment, variable transmission regions 540, 550 may extend beyond the ends of dark features 520, 530 by a distance in the range of about 2 to 20 nm. In an embodiment, variable transmission regions 540, 550 may extend beyond the ends of dark features 520, 530 by a distance in the range of about 8 to 12 nm. In other embodiments, variable transmission regions 540, 550 may be in the shape of serifs or hammerheads.

Variable transmission regions 540, 550 may reduce bright corner effects in photolithographic patterning of dark features 520, 530. In particular, in comparison to prior methods, such as serifs and hammerheads, variable transmission regions 540, 550 may provide less sensitivity to mask errors and increased image modulation.

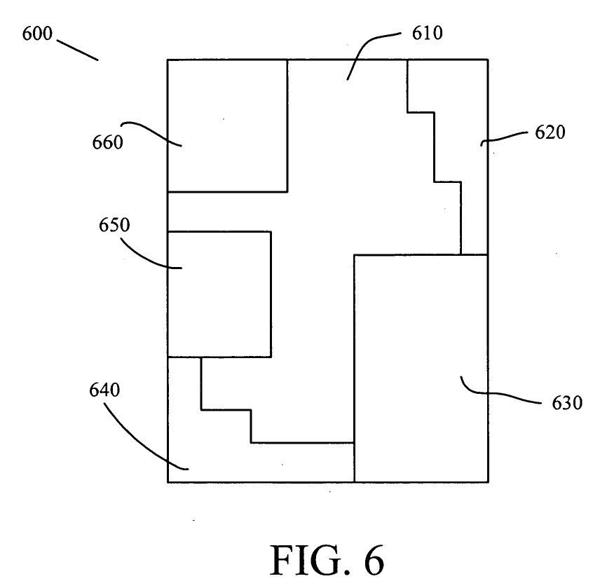

FIG. 6 illustrates a photo-mask 600 in accordance with an embodiment of the invention. Photo-mask 600 may reduce the sizing errors of elements or dark features on photo-mask 600. The sizing errors may be inherent in photo-mask fabrication. FIG. 6 illustrates areas 610, 620, 630, 640, 650, 660. Areas 610, 620, 630, 640, 650, 660 may have different transmittance values due to different implant concentrations in order to correct for sizing errors.

In general, if two dark features on a photo-mask are the same size, then the dark feature in an area of greater transmittance may form a smaller wafer level feature than the dark feature in an area of lesser transmittance under the same photolithography conditions. Therefore, areas of variable transmittance may be used to correct for dark feature sizing errors. In those areas where the dark features are smaller than desired and form smaller than desired wafer level features, reducing the transmittance in that area may cause the wafer level feature to be closer to the desired size.

Similarly, areas of different variable transmittance may also be used to correct for bright feature sizing areas. In those areas where the bright features are larger than desired and form larger than desired wafer level features, reducing the transmittance in that area may cause the wafer level feature to be closer to the desired size.

Any implant concentration may be used to affect a change in transmittance and wafer level feature sizes. In an embodiment, a transmittance change of about 2% may change the wafer level feature size of a dark feature by about 1 to 3 nm.

Any number of areas of variable transmittance may be used. In an embodiment, there may be a number of variable transmittance areas in the range of 3 to 10. In another embodiment, there may be a number of variable transmittance areas in the range of 2 to 15. In an embodiment, there may be a number of variable transmittance areas in the range of 4 to 8.

As illustrated in FIG. 6, areas 610, 620, 630, 640, 650, 660 may be arranged on photo-mask in any orientation. In particular, the layout of areas 610, 620, 630, 640, 650, 660 may depend on a sizing error determination, as is further discussed below.

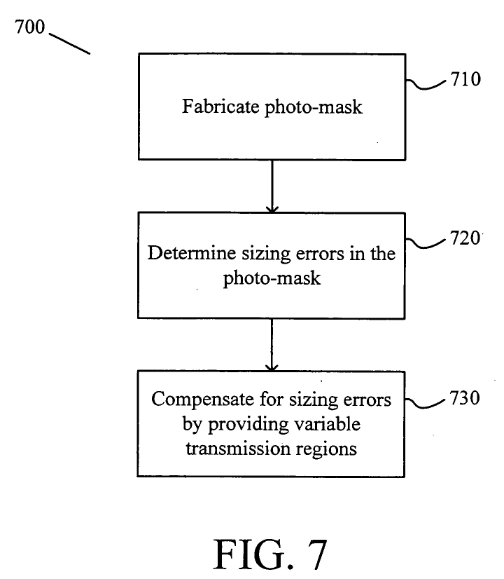

FIG. 7 illustrates an operational flow 700 in accordance with an embodiment of the invention. Operational flow 700 may be used to correct for photo-mask sizing errors. In box 710, a photo-mask may be fabricated according to any available technique. In some embodiments, the photo-mask may be a binary photo-mask features, EPSM features, chromeless phase shift mask features, or alternating phase shift mask features.

In box 720, the sizing errors of the photo-mask may be determined by any available technique. In an embodiment, the sizing errors may be determined by exposing a photo-sensitive film using the photo-mask and measuring feature sizes by a scanning electron microscope (SEM). In another embodiment, the sizing errors may be determined by scatterometry. In an embodiment, determining the sizing errors may include mapping areas of the photo-mask based on sizing errors. In an embodiment, the sizing errors may be determined by a combination of measurement and predictive methods, such as interpolation or extrapolation.

In box 730, the sizing errors may be compensated for. In an embodiment, the sizing error compensation may include providing variable transmission areas by implantation. In another embodiment, the sizing error compensation may include providing variable transmission areas by selective implantation. In an embodiment, the sizing error compensation may include providing variable transmission areas by patterning, implantation, and pattern removal.

In an embodiment, the feature sizes of the photo-mask fabricated in box 710 may be targeted with respect to variable transmission sizing error compensation. In an embodiment, dark features may be targeted with an average size that is smaller than the desired size. Then, lines that are larger than the targeted average may be of the actual desired size while those features that are smaller than desired may be compensated for using variable transmission sizing error compensation. Conversely, in an embodiment, bright features may be targeted with an average size that is larger than the desired size. Then, lines that are smaller than the targeted average may be of the actual desired size while those features that are larger than desired may be compensated for using variable transmission sizing compensation.

Reference throughout this specification to “one embodiment” or “an embodiment” means that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. A method comprising:
selectively implanting atoms into a surface of a photo-mask having discrete transmission areas to form a photo-mask including a variable transmission area.

2. The method of claim 1, wherein selectively implanting atoms includes implanting atoms with an ion beam.

3. The method of claim 1, wherein selectively implanting atoms includes forming a pattern layer on the photo-mask and a uniform implant on the pattern layer and photo-mask.

4. The method of claim 1, wherein the atoms include at least one of Silicon or Gallium.

5. The method of claim 1, wherein implanting atoms includes implanting atoms at a dosage in the range of about 1×10¹⁶ to 1×10¹⁸ atoms/cm².

6. The method of claim 1, wherein implanting atoms includes implanting atoms at an acceleration voltage in the range of about 20 to 40 kV.

7. The method of claim 1, wherein the photo-mask includes a dark feature on the photo-mask surface and implanting atoms includes selectively implanting atoms adjacent to the dark feature to provide for bright corner correction.

8. The method of claim 1, wherein the photo-mask comprises an alternating phase shift mask including elements on the photo-mask surface and selectively implanting atoms includes selectively implanting atoms into the elements.

9. The method of claim 1, further comprising:
annealing the atoms and the photo-mask.

10. The method of claim 1, further comprising:
performing a second selective implanting of atoms into the photo-mask surface to form a photo-mask including a second variable transmission area.

11. The method of claim 1, further comprising:
performing a plurality of selective atomic implants into the photo-mask surface to form a photo-mask including a plurality of variable transmission regions.

12. The method of claim 11, wherein the plurality of variable transmission regions correct for sizing errors.

13. The method of claim 12, further comprising:
determining sizing errors in the photo-mask.

14. The method of claim 1, further comprising:
forming a protective material over elements on the photo-mask; and
removing the protective material.

15. A method comprising:
designing a variable transmission area adjacent to a bright corner of a dark feature on a photo-mask including discrete transmission areas.

16. The method of claim 15, wherein the dark feature includes a line and the variable transmission region extends from beyond the end of the line to a distance of about 5 to 15 nm from the end of the line to a point within the extent of the line.

17. The method of claim 15, further comprising:
a second dark feature, wherein the dark feature includes a line and the end of the line terminates within a distance of about 60 to 100 nm from the second dark feature.

18. The method of claim 15, further comprising:
designing a second variable transmission area adjacent to the bright corner of the dark feature.

19. The method of claim 15, wherein the variable transmission region has a transmittance in the range of about 60 to 95%.

20. A method comprising:
at least partially compensating for sizing errors in a photo-mask having discrete transmission areas by selectively implanting atoms to form a photo-mask with variable transmission areas.

21. The method of claim 20, further comprising:
measuring the sizing errors of the photo-mask.

22. The method of claim 21, further comprising:
defining zones of the photo-mask for compensation.

23. The method f claim 20, further comprising:
fabricating the photo-mask, wherein fabricating the photo-mask includes fabricating the photo-mask with dark features that are smaller than a desired size.

24. The method of claim 20, further comprising:
performing a plurality of selective implants to form a photo-mask including a plurality of variable transmission regions.

25. An apparatus comprising:
an element on a surface of a photo-mask substrate; and
an implant region below the photo-mask surface that defines a variable transmission area, wherein the element, the photo-mask substrate, and the variable transmission area have different transmission values.

26. The apparatus of claim 25, wherein the implant region comprises at least one of Silicon or Gallium.

27. The apparatus of claim 25, wherein the element comprises a dark feature line and the variable transmission region is adjacent to the element and provides optical proximity correction for the element.

28. The apparatus of claim 25, wherein the photo-mask comprises at least one of a binary photo-mask, an embedded phase shift mask, a chromeless phase shift mask features, or an alternating phase shift mask features.

29. The apparatus of claim 25, further comprising:
a plurality of implant regions below the photo-mask surface.

30. The apparatus of claim 29, wherein the implant regions have different implant concentrations and compensate for photo-mask sizing errors.

31. The apparatus of claim 25, wherein the implant region has an implant concentration in the range of about 1×10¹⁹ to 1×10²² atoms/cm³.

32. The apparatus of claim 25, further comprising:
an implant region below a surface of the element, and wherein the photo-mask comprises an alternating phase shift mask.

33. The apparatus of claim 32, wherein the implant concentration of the implant region below the surface of the element is less than the implant concentration of the implant region below the photo-mask surface.
